(19) United States
(12) Patent Application Publication
(10) Pub. No.: US 2021/0305578 A1
(43) Pub. Date: Sep. 30, 2021

(54) A FILM MATERIAL AND A PROCESS OF PREPARING THE SAME

(71) Applicant: AGENCY FOR SCIENCE, TECHNOLOGY AND RESEARCH, Singapore (SG)

(72) Inventors: Vipin Kumar, Singapore (SG); Zhi Wei Seh, Singapore (SG)

(21) Appl. No.: 17/278,353

(22) PCT Filed: Sep. 5, 2019
(86) PCT No.: PCT/SG2019/050444

§ 371 Date: Mar. 22, 2021

(30) Foreign Application Priority Data
Sep. 24, 2018 (SG) 10201808331W

(51) Int. Cl. H01M 4/62; H01M 4/38; H01M 4/134; H01M 10/054; C23C 16/40; C23C 16/08

(52) U.S. Cl. CPC H01M 4/628; H01M 4/381; H01M 4/134; H01M 2004/027; C23C 16/40; C23C 16/08; H01M 10/054

(57) ABSTRACT

There is provided a film material comprising a combination of at least two metal compounds selected from the group consisting of a metal amide, a metal oxide, a metal halide and a metal alloy, wherein said metal is selected from Group I of the Periodic Table of Elements. There is also provided a process of preparing a film material comprising the step of contacting a solid phase material and a vapor phase material, wherein the solid phase material is a metal selected from Group 1 of the Periodic Table, and wherein the vapor phase material comprises a precursor selected from the group consisting of an amide precursor, an oxide precursor, a metal halide precursor and a metalloid halide precursor.

### REFERENCES TO RELATED APPLICATIONS

This application claims priority to Singapore application number 10201808331W filed on 24 Sep. 2018, the disclosure of which is hereby incorporated by reference.

### TECHNICAL FIELD

The present invention relates to a film material and a process of preparing the same for stable sodium metal anodes at room temperature.

### BACKGROUND ART

The sodium metal battery was first developed in 1966 at Ford Motor Company. The deployed version of sodium metal battery exists in the high-temperature form (350° C.) (grid energy storage), it is susceptible to catch fire, and not suitable for mobile applications, e.g., electric vehicles.

The room temperature version of sodium metal battery is difficult to realize due to poor stability of solid-electrolyte interphase (SEI) and sodium dendrite formation which may readily cause short-circuit of the cell.

An interphase is a thin region where two distinct chemical phases stabilize themselves, and it can be developed intrinsically or extrinsically (artificial interphase) over a parent phase (bulk phase). The intrinsic interphase grows itself and it is found to be less effective in preserving the integrity of the bulk phase. The properties of an intrinsic interphase are largely controlled by the intrinsic parameters, for instance, chemical potential or redox potential, which are complex and offer limited room to alter.

Modification of the anode and formation of ex-situ/in-situ interphases have been investigated to stabilize metal anode (at moderate currents). An ideal artificial interphase must be transparent enough to incoming ions, while it must be sufficiently opaque to the particles on the bulk phase. The artificial interphases developed hitherto comprise a single chemical component (mono-phasic interphase), which is effective in stabilizing sodium metal anode at low currents (<1 mA/cm2), while at high current rates, the stability is observed to be compromised.

Therefore, there is a need to provide a process and an interphase film for sodium metal anodes that overcome or ameliorate one or more of the disadvantages mentioned above.

### SUMMARY

In one aspect, the present disclosure relates to a film material comprising a combination of a metal amide with a metal oxide, or a combination of a metal halide with a metal alloy, wherein said metal is selected from Group I of the Periodic Table of Elements.

Advantageously, the film material can prevent dendrite formation and short-circuiting of an electrochemical cell. The combination of the at least two metal compounds is important as a film material comprising a single component (such as sodium oxide Na₂O alone) may not be able to stabilize sodium metal anodes at room temperature.

In another aspect, the present disclosure relates to a process of preparing a film material comprising the step of contacting a solid phase material and a vapor phase material,

wherein the solid phase material is a metal selected from Group 1 of the Periodic Table, and

wherein the vapor phase material comprises a combination of an amide precursor with an oxide precursor, or a combination of a metal halide precursor and a metalloid halide precursor.

Advantageously, the ex situ film material formed in the present disclosure can be developed without electrochemical treatment or any other additional process and with good control of film thickness. The attributes of the film material do not depend on the intrinsic parameters, and hence can be tuned to a great extent. On the other hand, other dissolved strategies offer little control on the physical and chemical properties and are more difficult to realize.

Further advantageously, the growth rate of the film material is in the range of 0.1 to 1 μm/s, which is much faster than other growth processes, such as atomic layer deposition (ALD). Even though slow growth process can offer good control over the film thickness, it may affect the integrity of sodium metal electrode. Alkali metal, in particular sodium metal, degrades quickly even in an inert gas atmosphere, therefore the interphase developed using a slow process might affect integrity of the sodium metal electrode.

In another aspect, the present disclosure relates to an interphase protected sodium metal anode, wherein said interphase is a film material as defined herein.

Advantageously, direct formation of the artificial interphase on sodium metal anode using ammonia vapor can offer great control of the electrode roughness and avoid the use of liquid ammonia which can readily dissolve the sodium metal.

Further advantageously, the sodium metal anode can be stabilized at room temperature as compared to other film protected anodes which require a higher temperature to function.

In another aspect, the present disclosure relates to an electrochemical cell comprising the sodium metal anode as defined herein.

Advantageously, the electrochemical cell exhibits ultra-long cycle life at relatively high current densities. The interphase film helps the electrochemical cell to endure at practical current densities and has the potential to survive at high capacity loads.

### Definitions

The following words and terms used herein shall have the meaning indicated:

The term “stable”, “stability” and grammatical variants thereof, in the contexts of this specification, refers to an electrode that can be operated with no sign of short circuiting and sudden increase of voltage or current.

The term “interphase” as used herein refers to a thin region where two distinct chemical phases stabilize themselves.

The term “extrinsically” as used herein refers to the preparation process of a film that is grown artificially to form an ex situ interphase.

The term “volatile” as used herein refers to a property of a substance, which can be used to describe how easily the substance vaporizes from a liquid phase or a solid phase to a gaseous phase at a given temperature and pressure. In general, a substance having a high vapour pressure may indicate a high volatility while a substance with a high boiling point can indicate low volatility.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means+/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and sub-generic groupings falling within the generic disclosure also form part of the disclosure. This includes the generic description of the embodiments with a proviso or negative limitation removing any subject matter from the genus, regardless of whether or not the excised material is specifically recited herein.

### DETAILED DISCLOSURE OF EMBODIMENTS

Exemplary, non-limiting embodiments of a film material will now be disclosed.

The film material comprises a combination of a metal amide with a metal oxide, or a combination of a metal halide with a metal alloy, wherein said metal is selected from Group I of the Periodic Table of Elements.

The metal may be selected from the group consisting of lithium, sodium and potassium. The metal may be sodium.

The metal halide may be selected from the group consisting of metal fluoride, metal chloride, metal bromide and metal iodide.

The metal alloy may further comprise an element selected from the group consisting of a transition metal, a Group 14 metal and a Group 14 metalloid. The metal alloy may be sodium-titanium alloy, sodium-tin alloy or sodium-silicon alloy.

The film material may be monophasic.

The film material may be biphasic. The idea of designing a biphasic interphase is advantageous as the presence of an extra chemical phase could act as a buffer. Artificial interphase comprising monophasic (single phase) system, for instance sodium halide, is found to stabilize sodium metal anode at moderate current densities; however, it is susceptible to dendrite formation and short circuiting at high current densities.

The thickness of the film material may be from about 3 to about 90 μm, from about 5 to about 90 μm, from about 10 to about 90 μm, from about 15 to about 90 μm, from about 20 to about 90 μm, from about 25 to about 90 μm, from about 30 to about 90 μm, from about 35 to about 90 μm, from about 40 to about 90 μm, from about 50 to about 90 μm, from about 60 to about 90 μm, from about 70 to about 90 μm, from about 80 to about 90 μm, from about 3 to about 80 μm, from about 3 to about 70 μm, from about 3 to about 60 μm, from about 3 to about 50 μm, from about 3 to about 40 μm, from about 3 to about 35 μm, from about 3 to about 30 μm, from about 3 to about 25 μm, from about 3 to about 20 μm, from about 3 to about 15 μm, from about 3 to about 10 μm or from about 3 to about 5 μm.

The thickness of the interphase film plays a vital role in determining the effectiveness of the interphase, because a thick interphase is likely to increases the diffusion barrier, while an extremely thin interphase is less effective in preserving the integrity of the metal anode.

The film material is ionically conducting (equivalent series resistance about 5 to 50Ω). On the other hand, the film material is electrically insulating (equivalent series resistance about 1 to 500 GΩ).

For the film material comprising sodium amide and Na₂O, the chemical composition of the interphase may be Na_{0.61}N_{0.11}H_{0.22}O_{0.28} as determined using X-ray photoelectron spectroscopy (XPS). A normalized formula unit can be expressed as Na_{5.5}NH₂O_{2.5}, and further rearranged to approximately NaNH₂+2.5(Na₂O).

Advantageously, the film material comprising a combination of a sodium amide with a sodium oxide or a combination of a sodium halide with a sodium alloy may exhibit negligible diffusion barrier (0.25 to 0.28 eV) at room temperature. The other film materials comprising phosphate or sulphate of alkali metals exhibit higher diffusion barrier (0.8 to 1.2 eV) as the ionic conduction in trisodium phosphate or disodium phosphate is highly sluggish at room temperature.

For the film material comprising sodium halide and a sodium containing binary compound, the chemical compositions at the immediate surface (thickness of about 3 to 5 nm) and beneath (thickness of about 10 to 12 nm) may be identified to be NaCl_{0.12}Sn_{0.02}, and NaCl_{0.03}Sn_{0.11}, respectively.

Exemplary, non-limiting embodiments of a process of preparing a film material will now be disclosed.

The process of preparing a film material comprises the step of contacting a solid phase material and a vapor phase material, wherein the solid phase material is a metal selected from Group 1 of the Periodic Table, and wherein the vapor phase material comprises a combination of an amide precursor with an oxide precursor, or a combination of a metal halide precursor and a metalloid halide precursor.

The Group I metal may be selected from the group consisting of lithium, sodium and potassium. The Group I metal may be sodium.

The metal of said metal halide precursor may be a transition metal or a Group 14 metal. The metal of said metal halide precursor may be titanium or tin.

The metalloid of said metalloid halide precursor may be a Group 14 metalloid. The metalloid of said metalloid halide may be silicon.

The halide of said metal halide precursor or said metalloid halide precursor may be selected from the group consisting of fluoride, chloride, bromide and iodide.

The oxide precursor may be water.

The amide precursor may be selected from the group consisting of anhydrous ammonia, anhydrous hydrazine, urea and ammonia water.

The ammonia precursor or the metal or non-metal halide precursor is preferred to be highly volatile. The vapour pressure of the precursor may be higher than 20 mmHg at ambient environment conditions (1 atm, and 30° C.).

The vapor concentration may be in the range of about 10 to about 900×10⁴ ppm, about 20 to about 900×10⁴ ppm, about 30 to about 900×10⁴ ppm, about 50 to about 900×10⁴ ppm, about 100 to about 900×10⁴ ppm, about 300 to about 900×10⁴ ppm, about 500 to about 900×10⁴ ppm, about 700 to about 900×10⁴ ppm, about 10 to about 700×10⁴ ppm, about 10 to about 500×10⁴ ppm, about 10 to about 300×10⁴ ppm, about 10 to about 100×10⁴ ppm, about 10 to about 50×10⁴ ppm, about 10 to about 30×10⁴ ppm, or about 10 to about 20×10⁴ ppm.

When the vapor phase material is an ammonia precursor, the vapor concentration may be in the range of about 600 to about 900×10⁴ ppm, about 650 to about 900×10⁴ ppm, about 700 to about 900×10⁴ ppm, about 750 to about 900×10⁴ ppm, about 800 to about 900×10⁴ ppm, about 850 to about 900×10⁴ ppm, about 600 to about 850×10⁴ ppm, about 600 to about 800×10⁴ ppm, about 600 to about 750×10⁴ ppm, about 600 to about 700×10⁴ ppm, or about 600 to about 650×10⁴ ppm.

When the vapor phase material is a metal or non-metal halide precursor, the vapor concentration may be in the range of about 10 to about 15×10⁴ ppm, about 11 to about 15×10⁴ ppm, about 12 to about 15×10⁴ ppm, about 13 to about 15×10⁴ ppm, about 14 to about 15×10⁴ ppm, about 10 to about 14×10⁴ ppm, about 10 to about 13×10⁴ ppm, about 10 to about 12×10⁴ ppm, or about 10 to about 11×10⁴ ppm.

The film material may be obtained at a growth rate of 0.1 μm/s to 1 μm/s, 0.2 μm/s to 1 μm/s, 0.3 μm/s to 1 μm/s, 0.5 μm/s to 1 μm/s, 0.8 μm/s to 1 μm/s, 0.1 μm/s to 0.8 μm/s, 0.1 μm/s to 0.5 μm/s, 0.1 μm/s to 0.3 μm/s, or 0.1 μm/s to 0.2 μm/s.

When the vapor phase material is an ammonia precursor, the film material may be obtained at a growth rate of about 0.1 μm/s. The film material may be obtained for a time duration of about 30 to about 300 s, about 40 to about 300 s, about 50 to about 300 s, about 80 to about 300 s, about 100 to about 300 s, about 150 to about 300 s, about 200 to about 300 s, about 250 to about 300 s, about 30 to about 250 s, about 30 to about 200 s, about 30 to about 150 s, about 30 to about 100 s, about 30 to about 80 s, about 30 to about 50 s, or about 30 to about 40 s.

When the vapor phase material is a metal- or non-metal halide precursor, the film material may be obtained at a growth rate of about 1.0 μm/s. The film material may be obtained for a time duration of about 10 to about 30 s, about 15 to about 30 s, about 20 to about 30 s, about 25 to about 30 s, about 10 to about 25 s, about 10 to about 20 s, or about 10 to about 15 s.

The film material may be obtained extrinsically. The idea of designing an artificial or ex-situ interphase over alkali metal anodes is considered to be advantageous because a controlled interphase can be developed with a great degree of manipulation.

The process may be spontaneous, and no external energy (in the form of temperature or pressure) is supplied to the system.

The present disclosure also provides an interphase protected sodium metal anode, wherein said interphase is a film material as defined herein.

The present disclosure further provides an electrochemical cell comprising the sodium metal anode as defined herein.

The electrochemical cell can be operated at a temperature range of 10 to 40° C., wherein the sodium anode is in solid form.

The electrochemical cell may further comprise an organic electrolyte and a polymer-based separator. The organic electrolyte may be selected from the group consisting of propylene carbonate (PC), ethylene carbonate (EC), acetonitrile (ACM), tetrahydrofuran (THF) and ether electrolytes. The separator may be selected from the group consisting of polypropylene, polyethylene, polyamide, cellulose, glass fiber and mixtures thereof.

With the interphase film material comprising a combination of a sodium amide with a sodium oxide, the electrochemical cell is stable over a period of at least 500 cycles with no sign of short circuiting at 1 mA/cm² current density and 1 mAh/cm² areal capacity at room temperature. The electrochemical cell is stable over a period of at least 300 cycles with no sign of short circuiting at current densities of 1 to 50 mA/cm² and 1 mAh/cm² areal capacity at room temperature. The electrochemical cell is stable over a period of at least 300 hours at areal capacities of 1-10 mAh/cm² at 1 mA/cm² current density at room temperature. The electrochemical cell is stable over a period of at least 40 cycles with no sign of short circuiting, at 1 mA/cm² current density and 1 mAh/cm² areal capacity at 40° C.

With the interface film material comprising a combination of a sodium halide with a sodium alloy, the electrochemical cell is stable over a period of at least 300 cycles at 2 mA/cm² current density and 1 mAh/cm² areal capacity at room temperature. The electrochemical cell is stable over a period of at least 100 cycles at 5 mA/cm² current density and 1 mAh/cm² areal capacity at room temperature.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIGS. 1A through 1D

FIGS. 1A through 1D show FESEM micrographs of the surface morphology of the sodium amide and sodium oxide interphase at various time spans at different magnifications (X 0.5K and X 3K), and FIGS. 1E through 1H show cross sectional micrographs of the interphase.

FIGS. 2A through 2F

FIGS. 2A through 2C show FESEM micrographs of the surface morphology of the sodium chloride and sodium-tin alloy interphase at various time spans, and FIGS. 2D through 2F show corresponding cross-sectional micrographs of the as-developed biphasic interphase.

FIGS. 3A through 3D

FIGS. 3A through 3C show Raman spectroscopy of the interphase and controlled optical micrographs in inset of (a) depict surface view of the controlled (pristine Na) and interphase (AW-Na), and FIG. 3D shows digital micrograph of the test assembly.

FIGS. 4A through 4C

FIGS. 4A through 4C show schematic illustration of the steps involved in the development of biphasic interphase, where, sphere represents atoms or ions, 100—Na atom, 200—Cl ion, 300—Sn ion, and 400—Sn atom.

FIGS. 5A through 5J

FIGS. 5A through 5D show EDS analyses of biphasic interphase in the surface configuration, FIGS. 5E through 5H show EDS analyses of biphasic interphase in the cross-sectional configuration, FIG. 51 shows Sn and Cl content as a function of thickness (recorded using X-ray photoelectron spectroscopy), and FIG. 5J shows schematic illustration of the biphasic interphase.

FIGS. 6A and 6B

FIG. 6A shows a schematic representation of the symmetric cell with interphase, and FIG. 6B shows a schematic representation of the symmetric cell without interphase: 100 is a current collector. 200 is a separator with electrolyte. 210 is a sodium positive electrode (cathode) with interphase. 220 is a sodium negative electrode (anode) with interphase. 230 is a sodium positive electrode (cathode). 240 is a sodium negative electrode (anode).

FIGS. 7A through 7E

FIG. 7A shows a constant current charge-discharge (strip-plate) test of the symmetric cells (AW-Na//AW-Na, Na with interphase) fabricated using various thickness of the interphase, FIGS. 7B through 7D show magnified views of strip-plate test at various time spans, and FIG. 7E shows mid voltage profile of charge-discharge at various thickness.

FIGS. 8A through 8J

FIGS. 8A through 8J show constant current charge-discharge (strip-plate) test of symmetric cell (AW-Na//AW-Na, Na with interphase, and Na//Na, pristine Na as control cell) at various applied current densities, where areal capacity was fixed at 1 mAh/cm².

FIGS. 9A and 9B

FIGS. 9A and 9B show the comparison of electrochemical cell stability without interphase protection (FIG. 9A) and with interphase protection (FIG. 9B). Sodium dendrite nucleation and growth occurred during with initial cycling and prolong cycling for pristine sodium metal. With interphase protection, uniform deposition of sodium was observed throughout the cycles with good stability.

FIGS. 10A through 10D

FIGS. 10A through 10D show constant current charge-discharge (strip-plate) test of symmetric cell (AW-Na//AW-Na, Na with interphase) at various areal capacities, where current density was fixed at 1 mA/cm².

FIG. 11

FIG. 11 shows constant current strip/plate (charge/discharge) test of the symmetric sodium cells (NaNH2/Na2O interphase and Na2O only interphase on Na metal) at 2 mA/cm² and 1 mAh/cm², at room temperature.

FIGS. 11A through 12D

FIGS. 12A through 12D show constant current charge-discharge (strip-plate at 2 mA/cm²) test of symmetric cells of (a) Na with biphasic interphase produced at various reaction time (FIG. 12A), (b) pristine (Na//Na) and with biphasic interphase (FIG. 12B), (c) monophasic (NaCl//NaCl) interphase and biphasic interphase (FIG. 12C), and (d) strip-plate test at higher applied current density (5 mA/cm²) (FIG. 12D).

FIGS. 13A through 13D

FIGS. 13A through 13D show constant current charge-discharge (strip-plate at 2 mA/cm²) test of the symmetric cells assembled using biphasic interphase produced using various sources of reacting species at different reaction times, (a) SnCl₄ vapors (FIG. 13A), (b) SiCl₄ vapors (FIG. 13B), (c) TiCl₄ vapors (FIG. 13C), and (d) stability comparison of the interphase derived using different reaction sources (FIG. 13D).

### EXAMPLES

Non-limiting examples of the invention and a comparative example will be further described in greater detail by reference to specific Examples, which should not be construed as in any way limiting the scope of the invention.

### Materials and Methods

Sodium electrode cubes (99.9%), aqueous ammonia (≥25% NH3 in H₂O), tin tetrachloride fuming (˜98%), silicon tetrachloride (˜99%), titanium tetrachloride solution (˜1M), 1-chloropropane and diethylene glycol dimethyl ether (diglyme, anhydrous), were all purchased from Sigma Aldrich Singapore. Sodium trifluoromethanesulfonate (NaCF₃SO₃, 99.5%) was obtained from Solvionic France. All the chemicals were used as received after drying in an argon filled MBraun glovebox (H₂O<0.1 ppm, and O2≤2 ppm) to ensure that they are free from ambient moisture.

### Example 1: Vapor Generation

When an ammonia precursor is used as the vapor phase material, the interphase was developed using solid-vapor approach, wherein pristine sodium metal and ammonia vapors served as a source of solid and vapor phase, respectively. The selection of the source of ammonia vapors is vital, as it largely determines the yield of the interphase. Ammonia water was used for its high vapor pressure (about 1800 mmHg at 27° C.) characteristics and its ease of availability.

In addition, the vapor pressure of ammonia water ultimately decides the concentration of ammonia vapors within the reaction vessel or chamber (which is typically a vial). The ultimate vapor concentration was determined to be in the range of 640-900×10⁴ ppm. There are two possibilities to tune the concentration of the reacting species in the vicinity of the sodium metal anode, first to increase the volume of the ammonia water and allow the vapors to react for a short period of time, and the other is to fix the volume and let the vapors to react with sodium metal for a longer time. The latter strategy offers better controllability on the process steps.

When a metal- or non-metal halide precursor is used as the vapor phase material, the source of vapors must contain at least one metal or semimetal element to form alloy with sodium and other has to be a halide, besides its high volatility and ease of availability. The interphase was developed using solid-vapor approach, wherein, pristine sodium metal and tin tetrachloride vapors served as source of solid and vapor phase, respectively. Tin tetrachloride (SnCl₄) vapors qualify as a primary source of biphasic interphase, and a weak interaction between SnCl₄ molecules promotes a facile dissociation of SnCl₄ into its constituents over alkali metallic surface. Atomic Sn readily forms alloy with sodium (Na) even at room temperature and at all given concentrations, and the highly electronegative chlorine preferentially interacts with Na to form sodium chloride. The selection of the source of metal halide vapors is vital, as it largely determines the yield of the interphase. Tin tetrachloride (SnCl₄), was used for its fuming characteristics (high volatility) and ease of availability.

The volatility of solution ultimately decides the concentration of reactive vapors within the reaction vessel or chamber (which is typically a glass vial). The ultimate vapor concentration was determined to be in the range of 13-15×10⁴ ppm. Since, the concentration of the reacting species is directly associated with the thickness of biphasic interphase, therefore, it is vital that the concentration of vapors to be tuned precisely.

### Example 2: Tuning the Thickness of the Interphase

The thickness of the artificial interphase plays a vital role in determining the effectiveness of the interphase, because a thick interphase is likely to increases the diffusion barrier, while an extremely thin interphase is less effective in preserving the integrity of the metal anode. The reaction between vapor phase of ammonia water or SnCl₄ and solid phase of sodium was spontaneous, as no external energy (in the form of temperature or pressure) was supplied to the system, and a sufficiently thick interphase could be grown.

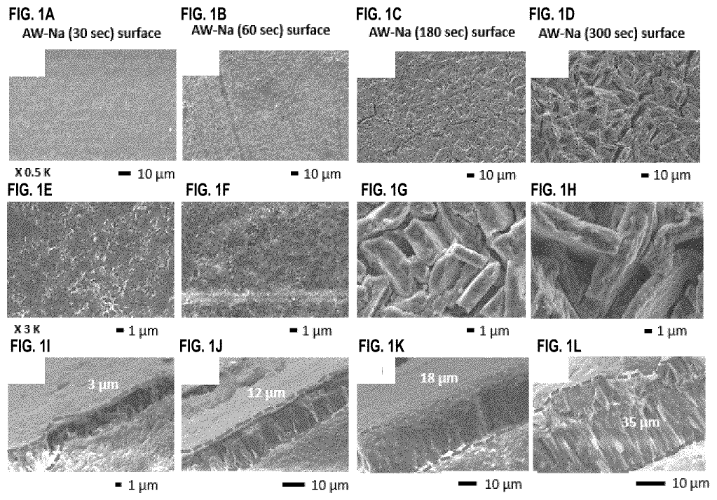

The reaction between vapor phase of ammonia water and solid phase of sodium was performed at various time spans, for example, 30 seconds, 60 seconds, 180 seconds, and 300 seconds, which yielded a distinct surface morphology in each case, FIGS. 1A through 1d. The growth rate of the interphase was recorded to be close to ˜0.12 μm/s, suggesting occurrence of spontaneous chemical reactions in the vicinity of sodium metal, the cross sectional micrographs are depicted in FIGS. 1E through 1H.

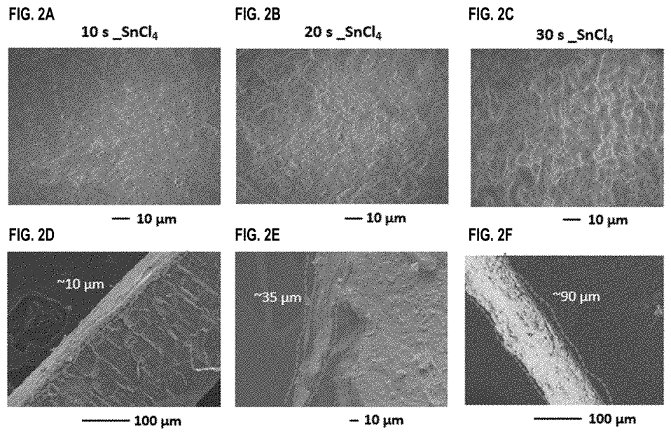

The reaction between vapor phase of SnCl₄ and solid phase of sodium was also performed at various time spans, for example, 10 seconds, 30 seconds, and 90 seconds, which yielded a distinct surface morphology and interphase thickness in each case as shown in FIGS. 2A through 2C, and the cross sectional micrographs are depicted in FIGS. 2D and 2F, respectively. The growth rate of the interphase was recorded to be close to ˜1.0 μm/s.

### Example 3: Reaction-Chemistry and Chemical Composition of the Interphase

The reaction chemistry occurring between solid-vapor phases of the reactants strongly influences the stability and chemical composition the interphase.

Liquid ammonia with water molecules is considered to be quite reactive and has the ability to partake in chemical reactions. The development of the interphase is a consequence of the reaction between sodium and ammonia water vapors, as represented in the following equation:

$$6 {Na}_{( s )} + 2 {NH}_{3} \cdot {H}_{2} {O}_{( v )} ⟶ 2 {NaNH}_{2 ( s )} + 2 {Na}_{2} {O}_{( s )} + 3 {H}_{2 ( g )}$$

The subscript refers to the physical state of the components before and after spontaneous reaction, wherein s denotes solid, v denotes vapor and g denotes gas.

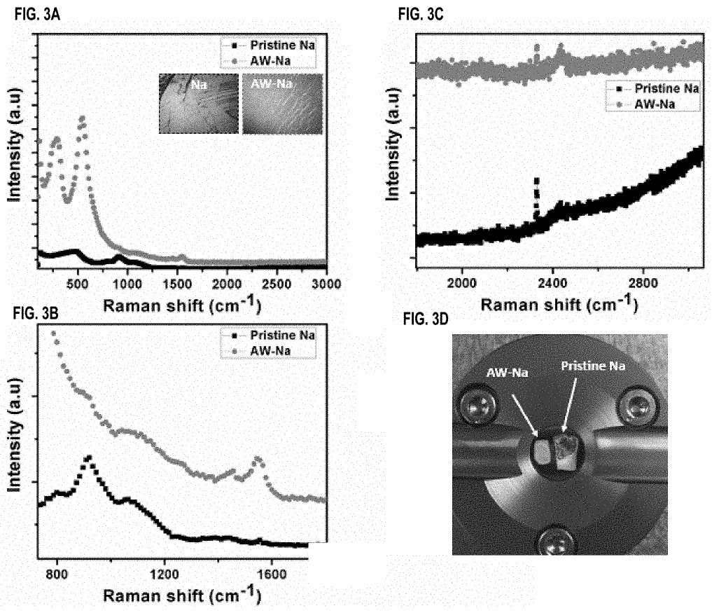

The chemical environment of the interphase was investigated using Raman spectroscopy, with pristine Na as comparison, as depicted in FIGS. 3A through 3C. The occurrence of vibrational bands at 1549 cm⁻¹, 545 cm⁻¹ and 280 cm⁻¹ suggested the presence of NaNH₂, and Na₂O, respectively, in the interphase, besides adsorption of the trace air impurities (e.g., CO/CO₂, N₂, O₂/H₂O, etc.).

The chemical composition of the aforementioned interphase was determined using X-ray photoelectron spectroscopy (XPS), and identified to be Na_{0.61}N_{0.11}H_{0.22}O_{0.28}. A normalized formula unit can be expressed as Na_{5.5}NH₂O_{2.5}, and further rearranged to approximately NaNH₂+2.5(Na₂O) to corroborate Raman spectroscopic findings.

The current-voltage (I-V) testing of a resistor device fabricated using interphase, revealed electrically insulating (˜GΩ) characteristics of the said interphase, and the observation of negative current (˜nA) at 0 V, was strongly suggesting cationic conduction (i.e., Na+ ions). Though the said interphase was electrically insulating, it unveiled a facile ionic conduction (equivalent series resistance ˜20Ω). An incremental increase in the series resistance was recorded with increase in the thickness. Due to minimal series resistance (˜20Ω) and lower interfacial barrier or overpotential (˜50 mV) exhibited by thinner interphase (˜3 μm, grown at 30 s reaction time), it was used for further evaluation.

For the biphasic interphase, it is identified that the reaction between sodium metal and SnCl₄ vapors favors the formation of two chemically distinct phases, i.e., NaCl and Na—Sn alloy. Spectroscopic and elemental analyses revealed the formation of NaCl over a thin region of Na—Sn alloy, which is developed directly on the sodium metal surface.

The formation of biphasic interphase is a consequence of the spontaneous reactions occurred in the vicinity of sodium metal according to the following equation:

$$5 {Na}_{ ( s )} + {SnCl}_{4 ( v )} ⟶ 4 {NaCl}_{ ( s )} + Na \text{-} {Sn}_{ ( s )}$$

The subscript refers to the physical state of the components before and after spontaneous reaction, wherein s denotes solid and v denotes vapor.

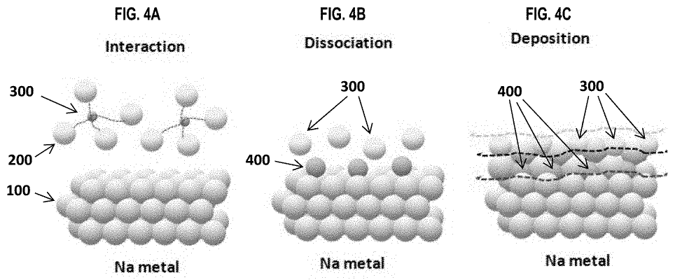

The process steps (interaction→dissociation→deposition) involved in the development of biphasic interphase are schematically illustrated in FIGS. 4A through 4C. The biphasic interphase comprises two distinct phase regions, where, an extremely thin (<5 nm) top layer is largely made of sodium chloride, and an alloy phase (i.e., Na—Sn alloy) is formed directly beneath the sodium chloride layer. The occurrence of geometric sequence of the phases lies in the fact that the size of chloride ions (0.167 nm) is slightly higher than that of tin atoms (0.145 nm), which in result affects the diffusion into the sodium lattice (nearly 32% space available).

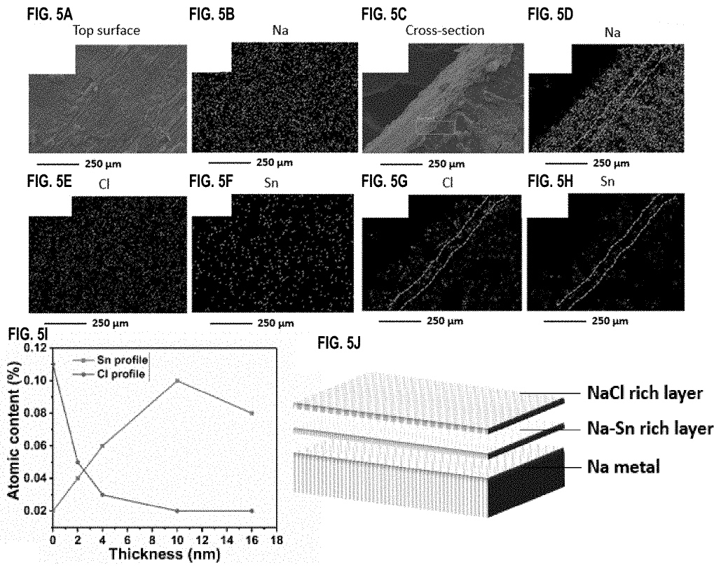

To examine the formation of the distinct chemical phases, energy dispersive X-ray spectroscopy (EDS) was performed in two different configurations of biphasic interphase, namely surface and cross-sectional. As depicted in FIGS. 5A through 5D, a uniform distribution of Na, Cl and Sn is identified on the surface of biphasic interphase. The cross-sectional EDS analyses further confirmed the distribution of Na, Cl, and Sn in biphasic interphase, however, the atomic percentage of Sn (˜2.1 atm. %) was much lower than that of Cl (˜11 atm. %) and Na (˜78 atm. %), as can be seen in FIGS. 5E through 5H. The atomic content of Sn and Cl was found to be varying with thickness of the interphase, as depicted in FIG. 51. The schematic representation of the biphasic interphase is shown in FIG. 5J.

The chemical composition of biphasic interphase was investigated at the surface and beneath the surface using X-ray photoelectron spectroscopy (XPS). The presence of Na, Cl and Sn was confirmed in biphasic interphase, and identified that the thickness of the top region is about 3-5 nm, which is primarily composed of sodium chloride (NaCl), and the subsequent chemical region is made of Na—Sn alloy. The chemical composition at the immediate surface and beneath (˜10-12 nm) the surface of biphasic interphase was identified to be NaCl_{0.12}Sn_{0.02}, and NaCl_{0.03}Sn_{0.11}, respectively.

### Example 4: Evaluation of the Electrochemical Stability of Interphase

The reversibility of the strip-plate process is essential for a metal anode to function at room temperature, and is often associated with stability of the charge-discharge (strip-plate) profiles.

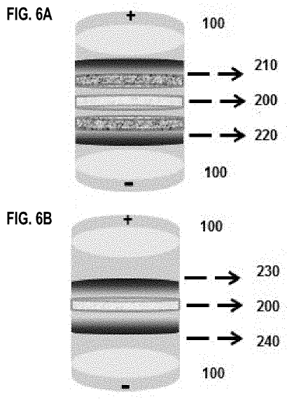

Symmetric cells comprising novel interphase were fabricated using two similar electrodes (1 cm²) separated by a polymer-based separator (celgard), and 25 μl of an organic electrolyte (digylme+sodium triflate) was used as a medium to conduct ionic charges. Schematic representation is depicted in FIGS. 6A and 6B.

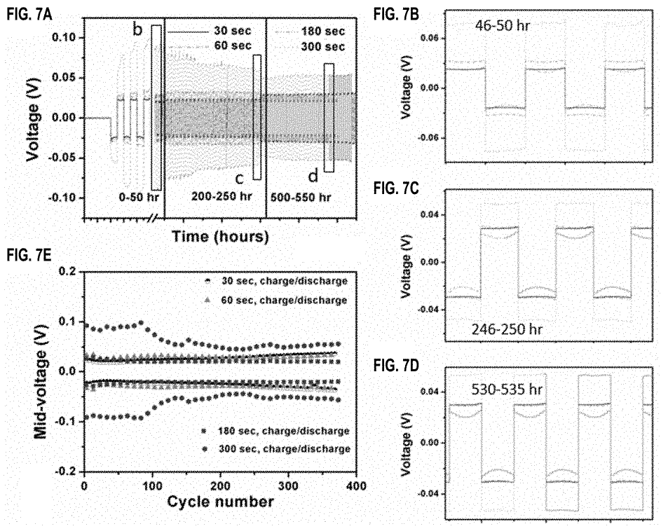

For the interphase consisting of NaNH₂ and Na₂O, the effect of the thickness on the overpotential was investigated by subjecting the symmetric cells to constant current charge-discharge test (sodium strip-plate). It was identified that the overpotential increases (from 50 mV to 180 mV) with the increase in the thickness (from 3 μm to 35 μm) of the interphase. Nevertheless, a facile charge discharge or conduction of sodium ions can be realized, despite the fact that a large overpotential was observed for thicker interphase, FIGS. 7A through 7E. As can be seen in FIG. 7E, thinner interphase (˜3 μm) experiences nearly uniform overpotential (throughout cycling span), which is only 27% of the overpotential exerted by a thicker interphase (˜35 μm), as result of its stability throughout the cycling span and lower overpotential, a thinner interphase (˜3 μm) was chosen for further evaluation.

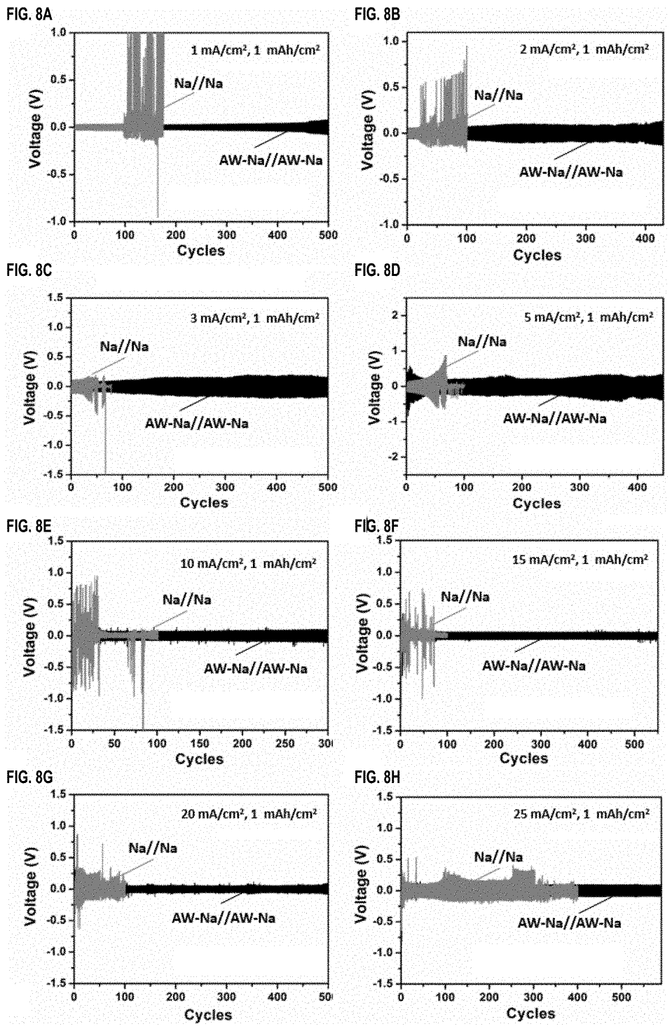

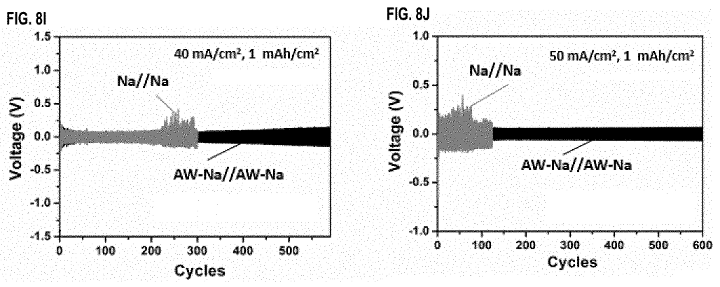

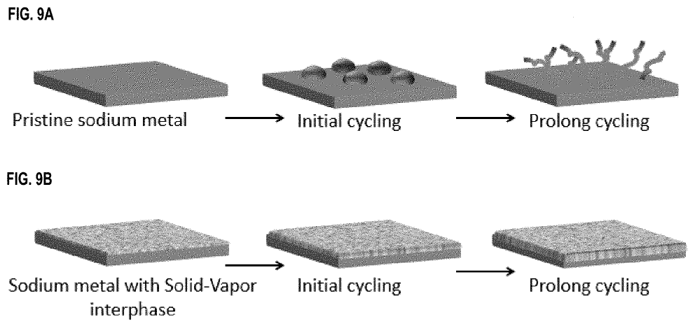

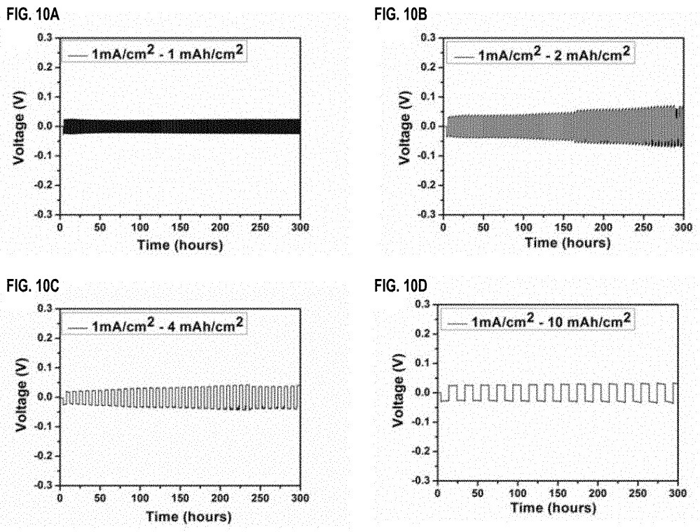

The cells (fabricated using thinner interphase, i.e., ˜3 μm) were subjected to various applied current densities, for instance, 1 mA/cm², 2 mA/cm², 3 mA/cm², 5 mA/cm², 10 mA/cm², 15 mA/cm², 20 mA/cm², 25 mA/cm², 40 mA/cm², and 50 mA/cm² where the areal capacity was fixed at 1 mAh/cm², as depicted in FIGS. 8A through 8J. A control cell comprising pristine sodium metal electrode was also fabricated. It was observed that the control cell is prone to short circuiting at all applied current densities in hundreds of hours, for instance, at an applied current density of 1 mA/cm², the control cell was short circuited within ˜200 hours (i.e., 100 cycles). In contrast, the cell comprising interphase was stable over at least 1000 hours (500 cycles, 2 hours per full cycle). As illustrated in FIGS. 9A and 9B, sodium dendrite nucleation and growth could occur during with initial cycling and prolong cycling for pristine sodium metal. With interphase protection, uniform deposition of sodium was observed throughout the cycles with good stability.

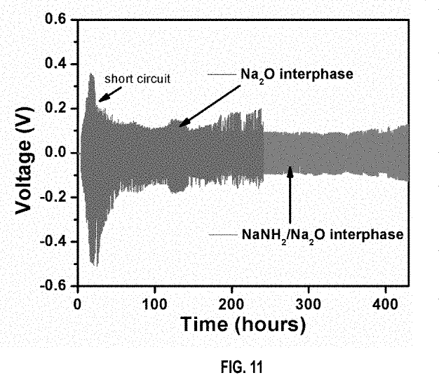

The cells were also subjected to various areal capacities, for instance, 1 mAh/cm², 2 mAh/cm², 4 mAh/cm², and 10 mAh/cm², where the applied current density was fixed at 1 mA/cm². Symmetric cells comprising novel interphase showed their stability over at least 300 hours at various areal capacities, as shown in FIGS. 10A through 10D. Further, our results showed that an interphase comprising Na₂O alone was unable to stabilize sodium metal anodes at room temperature (FIG. 11). Hence, a combination of Na₂O and NaNH₂ is necessary.

For the biphasic interphase consisting of sodium halide and sodium alloy, strip-plate profiles were evaluated in symmetric-cell configuration (i.e., Na//Na and Na with interphase//Na with interphase), where, various biphasic interphases (derived using different source of reacting species) were examined. We identified that Na metal anode with biphasic interphase derived using SnCl₄ vapors is highly stable over a period of at least 300 cycles at high applied current density of 2 mA/cm².

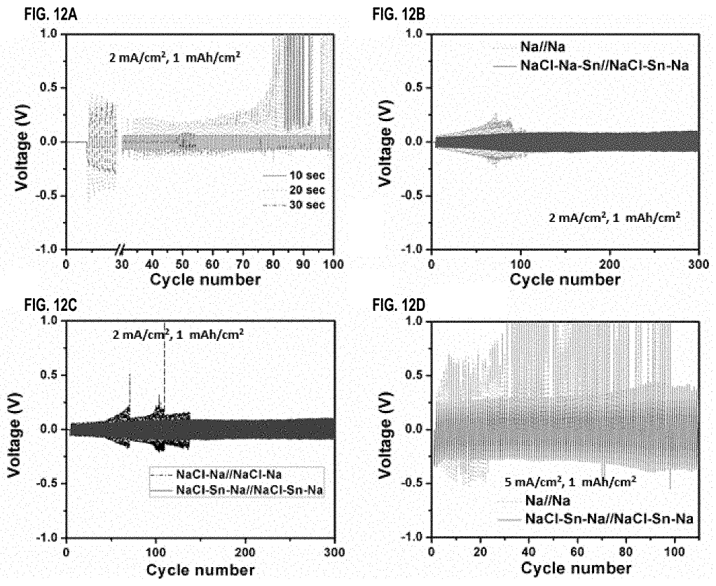

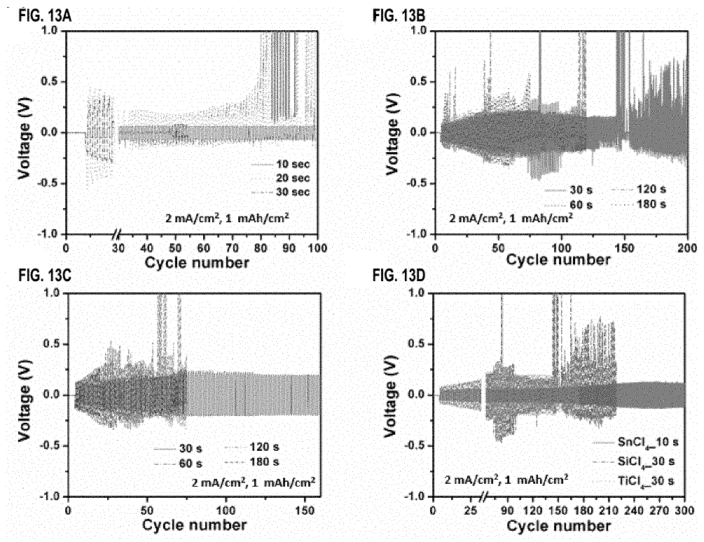

Symmetric cells fabricated using various thicknesses of biphasic interphase were examined, and identified that the interphase produced at 10 seconds reaction time stabilizes the metal anode more effectively than those produced at longer reaction times (i.e., 20 seconds, and 30 seconds), as depicted in FIG. 12A. Due to long term stability of biphasic interphase produced at 10 seconds reaction time, it was used for further studies.

The effectiveness of biphasic interphase became even more apparent when compared with pristine sodium metal anode, as depicted in FIG. 12B. The metal anode without biphasic interphase (i.e., Na//Na cells) is found susceptible to short-circuit within 60 cycles, whereas, the metal anode protected by biphasic interphase (i.e., NaCl—Sn—Na//NaCl—Sn—Na cells) is stable over a period of at least 300 cycles.

The effectiveness of biphasic interphase to stabilize Na metal anode was also evaluated with respect to monophasic interphase (i.e., NaCl interphase). It is evident from FIG. 12C that the monophasic NaCl interphase is less effective in preserving metal anode stability during strip-plate test; on the other hand, metal anode comprising biphasic interphase is highly stable over at least 300 cycles.

The stability of sodium metal anode with biphasic interphase was also evaluated even at higher applied current density (i.e. 5 mA/cm²) and it was identified that the metal anode can be cycled stably over a period of at least 100 cycles, as seen in FIG. 12D.

The effect of the other alloying elements on the effectiveness of biphasic interphase was also investigated. Besides SnCl₄, biphasic interphase was designed using other alloy forming reacting species, e.g., SiCl₄ and TiCl₄. The resulting biphasic interphase consists of NaCl and Na—Si/Na—Ti alloy. As can be seen in FIGS. 13A through 13C, sodium metal anode comprising biphasic interphase derived using SiCl₄ and TiCl₄ exhibit better stability over pristine sodium metal anode. However, these biphasic interphases are found to be less stable than that of SnCl₄ derived biphasic interphase, as can be seen in FIG. 13D.

### INDUSTRIAL APPLICABILITY

In the present disclosure, the process and the film material for the sodium metal anode may be applied to electrical vehicles, such as electrical car or motor bike. The process and the film material for the sodium metal anode may also be applied to grid energy storage.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A film material comprising a combination of a metal amide with a metal oxide, or a combination of a metal halide with a metal alloy, wherein said metal is selected from Group I of the Periodic Table of Elements.

2. The film material of claim 1, wherein said metal is selected from the group consisting of lithium, sodium, and potassium.

3. The film material of claim 1, wherein said metal halide is selected from the group consisting of metal fluoride, metal chloride, metal bromide, and metal iodide.

4. The film material of claim 1, wherein said metal alloy further comprises an element selected from the group consisting of a transition metal, a Group 14 metal, and a Group 14 metalloid.

5. The film material of claim 1, which is monophasic.

6. The film material of claim 1, which is biphasic.

7. The film material of claim 1, where the thickness of the film material is 3 μm to 90 μm.

8. A process of preparing a film material comprising a step of contacting a solid phase material and a vapor phase material, wherein:
the solid phase material is a metal selected from Group 1 of the Periodic Table, and
the vapor phase material comprises a combination of an amide precursor with an oxide precursor, or a combination of a metal halide precursor and a metalloid halide precursor.

9. The process of claim 8, wherein said Group I metal is selected from the group consisting of lithium, sodium, and potassium.

10. The process of claim 8, wherein said metal of said metal halide precursor is a transition metal or a Group 14 metal, or wherein said metalloid of said metalloid halide precursor is a Group 14 metalloid.

11. (canceled)

12. The process of claim 8, wherein the halide of said metal halide precursor or said metalloid halide precursor is selected from the group consisting of fluoride, chloride, bromide, and iodide.

13. The process of claim 8, wherein the oxide precursor is water, or wherein the amide precursor is selected from the group consisting of anhydrous ammonia, anhydrous hydrazine, urea and ammonia water.

14. (canceled)

15. The process of claim 8, wherein a vapor pressure of the precursor is higher than 22 mmHg at ambient environment conditions (1 atm and 30° C.), or wherein a vapor concentration of the vapor phase material is in a range of 10 to 900×10⁴ ppm.

16. (canceled)

17. The process of claim 8, wherein the film material is obtained at a growth rate of 0.1 μm/s to 1 μm/s.

18. An interphase protected sodium metal anode, wherein said interphase is a film material of claim 1.

19.-20. (canceled)
